(19) United States
(12) Patent Application Publication
(10) Pub. No.: US 2008/0289799 A1
(43) Pub. Date: Nov. 27, 2008

(54) HEAT DISSIPATION DEVICE WITH A HEAT PIPE

(75) Inventors: JUN LUO, Shenzhen (CN); CUI-JUN LU, Shenzhen (CN); CHIN-LUNG CHEN, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: FOXCONN TECHNOLOGY CO., LTD., Tu-Cheng (TW)

(21) Appl. No.: 11/752,910

(22) Filed: May 23, 2007

(51) Int. Cl. F28D 15/02; H05K 7/20

(52) U.S. Cl. 165/80.3; 165/104.13; 361/700

(57) ABSTRACT

A heat dissipation device includes a plurality of first fins and second fins, a flattened heat pipe and a base plate. The first fins include a first face at a bottom thereof. The second fins are sandwiched between the first fins and have a second face at a bottom thereof. The heat pipe includes a first section, a second section and a connecting section connecting the first section with the second section. The first section and the second section thermally contact the second face of the second fins. The connecting section thermally contacts the first face of the first fins. The base plate has a bottom surface adapted for contacting a heat-generating electronic component, and a top surface contacting the second face of the second fins and the first section and the second section of the heat pipe.

### BACKGROUND OF THE INVENTION

1. Field of the Invention

The present invention generally relates to heat dissipation devices, and more particularly to a heat dissipation device having a heat pipe for cooling an electronic component, such as an integrated circuit package.

2. Description of Related Art

Electronic components, such as central processing units (CPUs) comprise numerous circuits operating at high speed and generating substantial heat. Under most circumstances, it is necessary to cool the CPUs in order to maintain safe operating conditions and assure that the CPUs function properly and reliably. In the past, various approaches have been used to cool electronic components. Typically, a finned metal heat sink is attached to an outer surface of a CPU to remove the heat therefrom.

A typical heat sink generally comprises a base contacting with a CPU and a plurality of fins arranged on the base. In use, most of heat generated by the CPU is absorbed by the base, and is then conducted upwardly from the base to the fins to be dissipated to ambient air. However, only a part of the base, usually a middle part of the base, contacts the CPU to absorb heat from the CPU. The heat generated by the CPU is directly absorbed by the middle part of the base, but cannot quickly spread to other parts of the base. This results in an overheating of the middle part of the base, while the temperature of the other parts of the base is low. The fins on the other parts of the base positioned away from the middle part are not efficiently used. Heat dissipation efficiency of the heat sink is poor because of insufficient use of the fins on the base.

Accordingly, what is needed is a heat dissipation device which has an enhanced heat dissipation performance and low cost.

### SUMMARY OF THE INVENTION

According to an embodiment of the present invention, a heat dissipation device includes a plurality of first fins and second fins, a flattened heat pipe and a base plate. The first fins include a first face at a bottom thereof. The second fins are sandwiched between the first fins and have a second face at a bottom thereof. The heat pipe includes a first section, a second section and a connecting section connecting the first section with the second section. The first section and the second section thermally contact the second face of the second fins. The connecting section thermally contacts the first face of the first fins. The base plate has a bottom surface adapted for contacting a heat-generating electronic component, and a top surface contacting the second face of the second fins and the first section and the second section of the heat pipe.

Other advantages and novel features will become more apparent from the following detailed description of preferred embodiment when taken in conjunction with the accompanying drawings.

### BRIEF DESCRIPTION OF THE DRAWINGS

Many aspects of the present heat dissipation device can be better understood with reference to the following drawings. The components in the drawings are not necessarily drawn to scale, the emphasis instead being placed upon clearly illustrating the principles of the present heat dissipation device. Moreover, in the drawings, like reference numerals designate corresponding parts throughout the several views.

FIG. 1 is an exploded, isometric view of a heat dissipation device in accordance with a preferred embodiment of the present invention;

FIG. 2 is an inverted view of FIG. 1; and

FIG. 3 is an assembled view of FIG. 2.

### DETAILED DESCRIPTION OF THE INVENTION

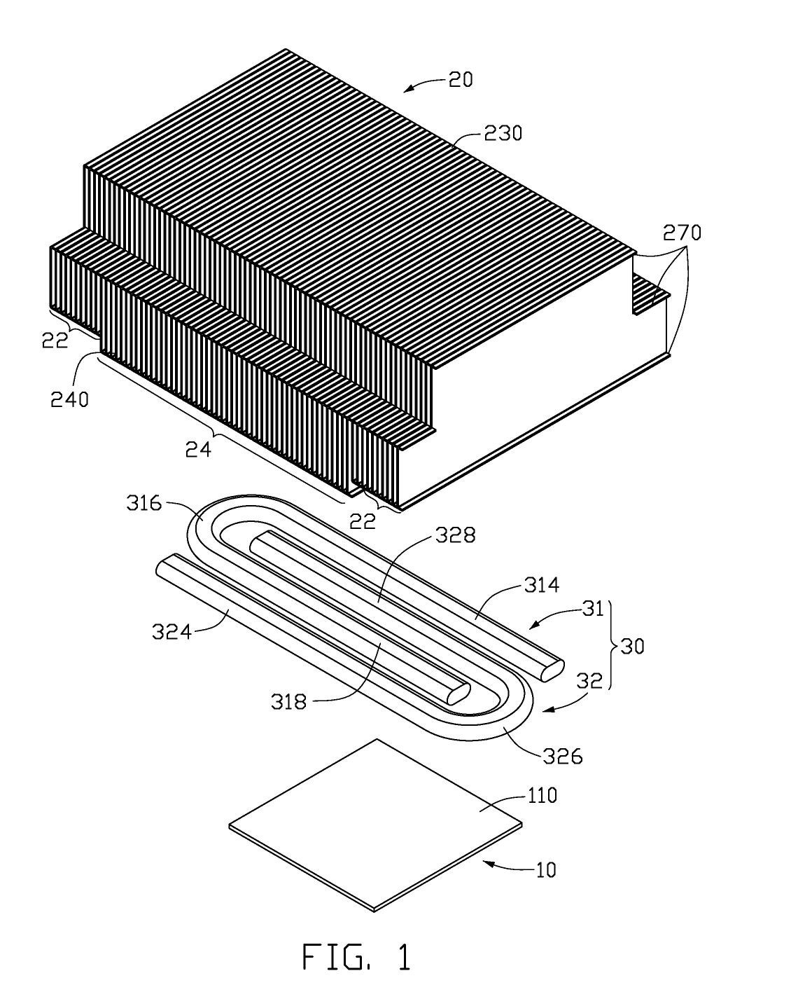

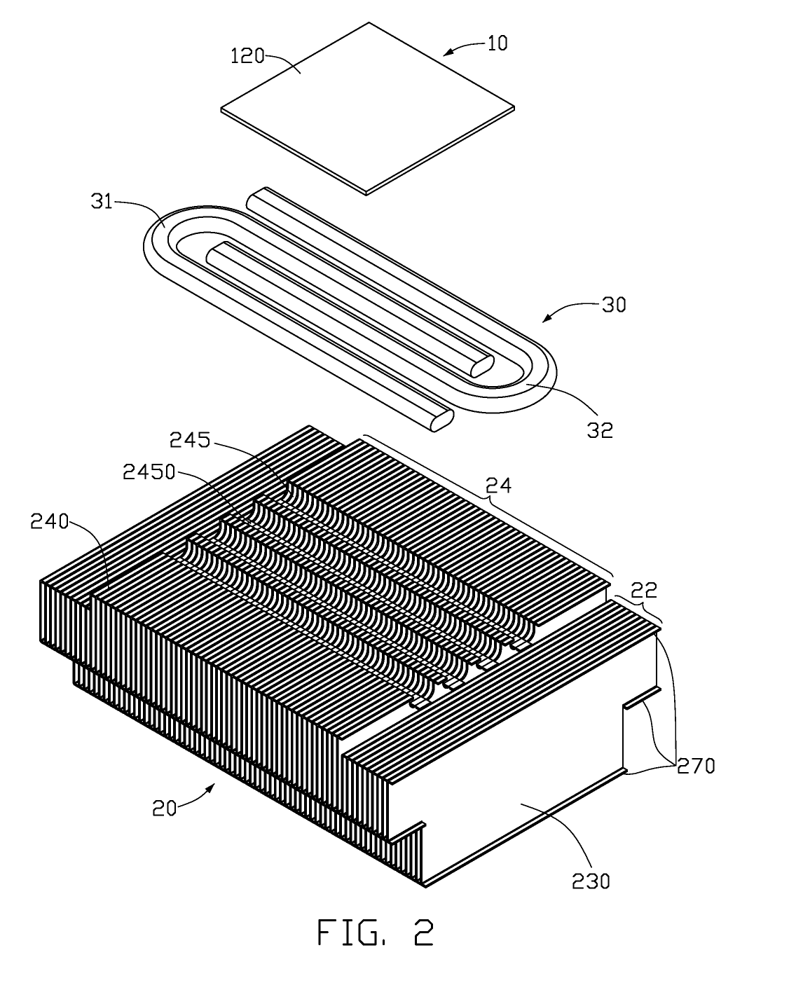

Referring to FIGS. 1-3, a heat dissipation device in accordance with a preferred embodiment of the present invention is shown. The heat dissipation device is for being mounted to a printed circuit board (not shown) to remove heat from a heat-generating electronic component (not shown) mounted on the printed circuit board, such as a CPU (not shown). The heat dissipation device comprises a base plate 10 for contacting the CPU, a fin assembly 20, and a heat pipe unit 30 located between the base plate 10 and the fin assembly 20. The heat pipe unit 30 comprises a first heat pipe 31 and a second heat pipe 32 thermally sandwiched between the fin assembly 20 and the base plate 10 for transferring heat from the base plate 10 to the fin assembly 20.

The base plate 10 is a substantially rectangular, thin plate, and is made of good thermal conductive material such as copper or aluminum. The base plate 10 has a flat top surface 110 supporting the heat pipes 31, 32 and a flat bottom surface 120 for directly contacting the CPU to absorb heat therefrom. In this embodiment, the base plate 10 is larger than the CPU and smaller than a bottom of the fin assembly 20.

The fin assembly 20 comprises a plurality of first fins 22 and a plurality of second fins 24. The assembly 20 has the second fins 24 at a middle portion thereof and the first fins 22 at two opposite lateral portions thereof. The first and second fins 22, 24 are parallel to each other and oriented perpendicular to the first and second heat pipes 31, 32 and the base plate 10. The second fins 24 are horizontally and longitudinally sandwiched between the first fins 22. The first and second fins 22, 24 each have an inverted T-shaped configuration so that the fin assembly 20 upwardly forms a longitudinal protruding portion 230 at an upper portion thereof, and has two lateral ends of a bottom portion thereof protruding outwardly. Each of the first and second fins 22, 24 is a thin sheet metal plate. In the fin assembly 20, bottoms (not labeled) of the second fins 24 are lower than bottoms (not labeled) of the first fins 22 so that the fin assembly 20 forms a protruding portion 240 protruding downwards from the bottom thereof. Each of the first and the second fins 22, 24 forms flanges 270 perpendicularly extending from a top edge and a bottom edge thereof. In the fin assembly 20, the flanges 270 at the top edges of the first, second fins 22, 24 forms a top face (not labeled). The flanges 270 at the bottom edges of the first fins 22 forms two bottom faces (not labeled) at two opposite sides of the second fins 24. The flanges 270 at the bottom edges of the second fins 24 forms a bottom face (not labeled) at the bottom of the fin assembly 20. The bottom face of the second fins 24 is lower than the bottom faces of the first fins 22. The second fins 24 define four transverse parallel grooves 245 in the protruding portion 240 for receiving the heat pipes 31, 32 therein. The second fins 24 at peaks 2450 of the grooves 245 are level with the bottom faces of the first fins 22.

The first heat pipe 31 is U-shaped in profile and has a flattened top face and a flattened bottom face. The first heat pipe 31 comprises two separate parallel first, second sections 314, 318 and an arced connecting section 316 connecting the first, second sections 314, 318. The second heat pipe 32 has a configuration similar to that of the first heat pipe 31. The second heat pipe 32 comprises two parallel first, second sections 324, 328 and an arced connecting section connecting the first, second sections 324, 328. The first sections 314, 324 are longer than the second sections 318, 328 of the first, second heat pipes 31, 32.

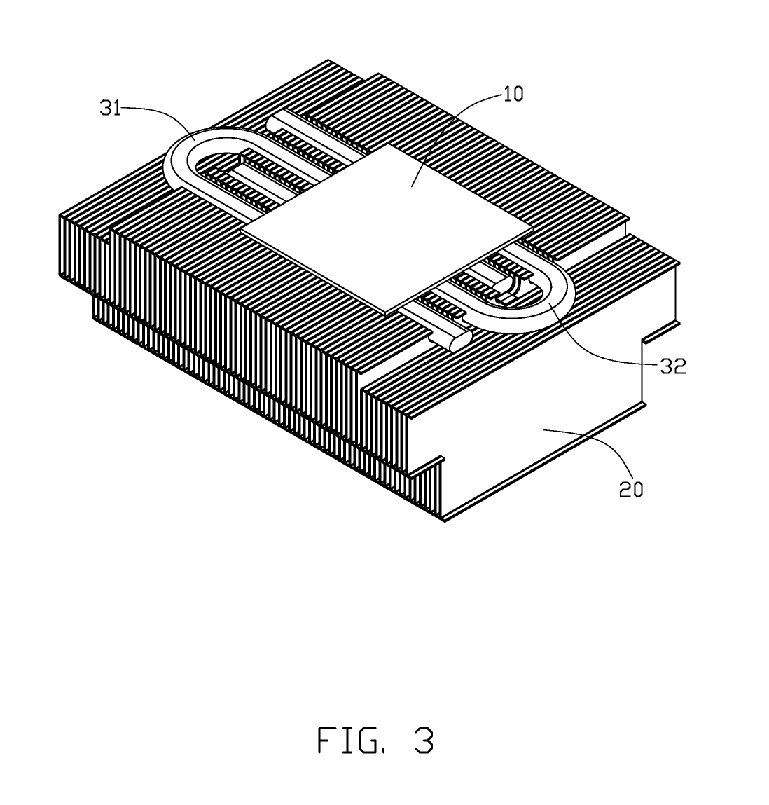

Referring also to FIG. 3, in assembly of the heat dissipation device, the first, second sections 314, 318, 324, 328 of the first, second heat pipes 31, 32 are thermally received in corresponding grooves 245 of the fin assembly 20 by soldering or other means. The arced connecting sections 316, 326 of the first, second heat pipes 31, 32 are soldered to the bottom faces of the first fins 22. The bottom faces of the heat pipes 31, 32 are coplanar with the bottom face of the protruding portion 240 of the fin assembly 20. The base plate 10 is soldered to the protruding portion 240 with the top surface 110 thereof thermally engaging with the bottom faces of heat pipes 31, 32 and the bottom face of the protruding portion 240. The first, second heat pipes 31, 32 are so configured between the base plate 10 and the fin assembly 20 that they are opened to each other and cross with each other. The first heat pipe 31 has the second section 318 thereof located between the first section 324 and the second section 328 of the second heat pipe 32. The second heat pipe 32 has the second section 328 thereof located between the first section 314 and the second section 318 of the first heat pipe 31. The first, second sections 314, 324, 318, 328 of the first, second heat pipes 31, 32 and their connecting sections project beyond two lateral sides of the base plate 10.

When the heat dissipation device is used, the base plate 10 is attached to the CPU with the bottom surface 120 in contact with the CPU. Heat generated by the CPU is absorbed by the base plate 10. A part of the heat in the base plate 10 is absorbed by portions of the heat pipes 31, 32 engaging with the base plate 10, and is quickly and evenly transferred to other portions of the first, second heat pipes 31, 32 engaging with the fin assembly 20. The heat in the heat pipes 31, 32 is transmitted to the fin assembly 20. Another part of the heat in the base plate 10 is directly transferred to fin assembly 20. The fin assembly 20 dissipates the heat to ambient air.

According to the embodiment of the present invention, the base plate 10 is of relatively thin construction, thus helping to reduce the cost of the heat dissipation device and further reduce heat resistance thereof to quickly transfer heat from the CPU to the first, second heat pipes 31, 32 and the fin assembly 20. The flattened heat pipes 31, 32 directly thermally contact with most of the fins 22, 24 of the fin assembly 20, which enlarges contacting area therebetween, and makes full use of the fins 22, 24 of the fin assembly 20; heat from the CPU can be transferred to most portions of the fin assembly 20 to be dissipated, thus improving the heat dissipation efficiency of the heat dissipation device. In addition, because the arced connecting sections 316, 326 of the first, second heat pipes 31, 32 directly engage with the first fins 22, the fin assembly 20 only needs to define grooves 245 for receiving the first, second sections 314, 318, 324, 328 of the heat pipes 31, 32 and does not need arced grooves to receive the connecting sections 316, 326; thus reducing manufacturing cost of the heat dissipation device.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device comprising:
a plurality of first fins comprising a first face at a bottom thereof;
a plurality of second fins sandwiched between the first fins and having a second face at a bottom thereof;
a flattened heat pipe comprising a first section, a second section and a connecting section connecting the first section with the second section, the first section and the second section thermally contacting the second face of the second fins, the connecting section thermally contacting the first face of the first fins; and
a base plate having a bottom surface adapted for contacting with a heat-generating electronic component, and a top surface contacting the second face of the second fins and the first section and the second sections of the heat pipe.

2. The heat dissipation device as described in claim 1, wherein the base plate is smaller than the bottom of the second fins.

3. The heat dissipation device as described in claim 2, wherein ends of the first section, the second section and the connecting section of the heat pipe project beyond the base plate.

4. The heat dissipation device as described in claim 1, wherein the first face of the first fins is at a different level to the second face of the second fins.

5. The heat dissipation device as described in claim 1, wherein the heat pipe defines a U-shaped configuration, the first section and the second section of the heat pipe being parallel to each other.

6. The heat dissipation device as described in claim 1 further comprising an additional heat pipe, wherein the additional heat pipes is so oriented that it opens to a direction opposite to that of the heat pipe.

7. The heat dissipation device as described in claim 1, the additional heat pipe has a section thereof located between the first section and the second section of the heat pipe.

8. The heat dissipation device as described in claim 1, wherein each of the first fins is a thin metal sheet and has a T-shaped configuration.

9. The heat dissipation device as described in claim 8, wherein each of the second fins is a thin metal sheet and has a T-shaped configuration.

10. The heat dissipation device as described in claim 1, wherein the first fins and the second fins are parallel to each other.

11. The heat dissipation device as described in claim 1, wherein the first fins and the second fins are oriented perpendicular to the heat pipe.

12. The heat dissipation device as described in claim 1, wherein the second face of the second fins defines two grooves for receiving the first section and the second section of the heat pipe.

13. The heat dissipation device as described in claim 12, wherein the second fins at a peak of the grooves are level with the first face of the first fins.

14. The heat dissipation device as described in claim 1, wherein each of the first fins and the second fins forms flanges perpendicularly extending from a top edge and a bottom edge thereof.

15. A heat dissipation device for dissipating heat generated by an electronic component, comprising:
a fin assembly consisting of a plurality of fins, having a bottom surface divided into a first portion and a second portion wherein the first portion is lower than the second portion and defines at least a groove therein, peak of the at least a groove being level with the second portion of the bottom surface;
at least a heat pipe received in the at least a groove, having at least a portion extending out of the at least a groove into the second portion of the bottom surface; and
a base plate having a bottom surface adapted for contacting with the electronic component and a top surface soldered to the first portion of the bottom surface of the fin assembly and thermally engaging with the at least a heat pipe.
